(19) United States
(12) Patent Application Publication
(10) Pub. No.: US 2007/0063272 A1
(43) Pub. Date: Mar. 22, 2007

(54) SEMICONDUCTOR POWER DEVICE WITH INSULATED GATE FORMED IN A TRENCH, AND MANUFACTURING PROCESS THEREOF

(75) Inventors: Giuseppe Arena, Catania (IT); Cateno Marco Camalleri, Catania (IT); Stefania Fortuna, Acicastello (IT); Angelo Magri, Belpasso (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS S.R.L., Agrate Brianza (IT)

(21) Appl. No.: 11/531,796

(22) Filed: Sep. 14, 2006

(30) Foreign Application Priority Data
Sep. 15, 2005 (IT) TO2005A 000630

(51) Int. Cl. H01L 29/94

(52) U.S. Cl. 257/330; 438/259

(57) ABSTRACT

A semiconductor power device has a semiconductor body with a first conductivity type. A trench extends in the semiconductor body and accommodates an insulating structure, which extends along the side walls and bottom of the trench. The insulating structure surrounds a conductive region, arranged on the bottom of the trench, and a gate region, arranged on top of the conductive region, the conductive region and the gate region being electrically insulated by an insulating layer. A body region, with a second conductivity type, extends within the semiconductor body, at the sides of the trench, and a source region, with the first conductivity type, extends within the semiconductor body, at the sides of the trench and within the body region. The conductive region and the gate region are both of polycrystalline silicon but have different conductivities and doping levels so as to have different electrical characteristics such as to improve the static and dynamic behaviour of the device.

### BACKGROUND OF THE INVENTION

1. Field of the Invention

The present invention relates to an insulated-gate semiconductor power device and to the manufacturing process thereof. More specifically, the invention relates to a power MOS device of the type comprising a trench used for insulating the gate region of the device (hereinafter indicated as power MOS device of the trench-gate type).

The invention relates, in particular, but not exclusively, to a power MOS device or a device of the IGBT (Insulated-Gate Bipolar Transistor) type, and the following description is made with reference to this application field, with the only purpose of simplifying its exposition.

2. Description of the Related Art

As is known, power MOS devices comprise a plurality of cells, each having a gate region adjacent to body and source regions. In the manufacturing process of trench-gate power MOS devices, the gate of the MOS structure is formed in each elementary cell of the device by making, in the silicon substrate, a trench, the walls whereof are coated with a thin oxide layer, referred to as gate oxide, and by then completely filling the trench with polysilicon. In this structure, the channel of the device is formed along the vertical walls of the trench.

This MOS structure, formed by stacking silicon, oxide, and polycrystalline silicon, has considerable advantages with respect to a device obtained with planar technology. In fact, the resistance associated to the JFET area, due to the opposed body wells of the device, is totally eliminated, thus improving the conduction characteristic of the device. Furthermore, the dimensions of the device are accordingly scaled, with consequent increase in the current-carrying capability.

On the other hand, this structure presents some problems. In fact, in the bottom area of the trench a densification of the lines of the electric field is created, which determines, given the same current-carrying capacity, a decrease in the breakdown voltage of the device.

Furthermore, as compared to a planar structure, there arises, given the same active area, a considerable increase in the area of the gate oxide, also in useless areas, where the channel is not formed, i.e., in those parts of the gate oxide that extend underneath the body region. The increase in area occupied by the gate oxide leads to an increase in the parasitic capacitances linked to the gate terminal of the device and, hence, of the gate charge, as compared to the planar structures.

### BRIEF SUMMARY OF THE INVENTION

The first problem (crowding of the electric-field lines) is currently solved by making the trench with a U-shaped profile, rounded at its bottom end. In this way, in fact, the resistance to breakdown of the device is improved.

The second problem (increase in the gate oxide area), instead, is solved either by depositing a thick oxide layer in the trench so as to coat only the bottom of the trench following its U-shaped profile and thus forming a double layer of gate oxide in the bottom part of the trench (see, for example, U.S. Pat. No. 6,528,355 B2), or by depositing a thick oxide layer in the trench to coat the bottom of the trench and fill it up to a certain height.

The advantages of the above two process solutions are numerous:

the breakdown voltage of the device increases because the thick oxide layer performs the function of “field ring”, i.e., that of preventing crowding of the electric field lines at the bottom of the trench;

the breakdown voltage of the gate oxide increases because the thin gate oxide no longer comprises the part of the wall where there is a variation of crystallographic orientation of the silicon; in this area, in fact, the thickness of the gate oxide is not controllable and could cause premature failure of the device;

the parasitic capacitance associated to the gate terminal of the device decreases.

In practice, a favorable compromise is created between the increase in the breakdown voltage and the reduction of the output resistance of the device.

In particular, the solution that envisages a U-shaped thick oxide on the bottom of the trench provides better performance as regards the improvement of the breakdown voltage (higher values are obtained), while the second solution (thick oxide that completely fills the bottom of the trench) behaves relatively better in regard to parasitic capacitance.

One embodiment of the present invention provides a power device of the type referred to above that yields a better compromise as to the two above aspects so as to present a substantially improved behavior as regards both breakdown and parasitic capacitance.

In practice, to reconcile both the static aspect and the dynamic aspect of the device, the polysilicon region that fills the trench is divided into two parts with different physical and electrical characteristics. According to one embodiment of the invention, the bottom part is formed by a lightly doped polysilicon of a type opposite to the polysilicon of the top part (which forms the gate region) so as to function as an electrode with reverse biasing. In this way, the device maintains the breakdown gain of the known solution described above with U-shaped thick oxide and has an improved dynamic behaviour in so far as the bottom part of polysilicon can undergo depletion during switching and thus provides a minor contribution to the capacitance of the polysilicon region.

### BRIEF DESCRIPTION OF THE SEVERAL VIEWS OF THE DRAWING(S)

For a better understanding of the invention, some preferred embodiments thereof are now described purely by way of non-limiting example and with reference to the attached drawings, wherein:

FIGS. 1 to 11 show cross-sections through a semiconductor wafer in successive manufacturing steps of the device, according to a first embodiment of the invention;

FIG. 12 is a cross-section of a power MOS device, according to a second embodiment of the invention;

FIG. 13 is a cross-section of a power MOS device according to a third embodiment of the invention;

FIG. 14 is a cross-section of a power MOS device, according to a fourth embodiment of the invention; and

FIG. 15 is a cross-section of a power MOS device, according to a fifth embodiment of the invention.

### DETAILED DESCRIPTION OF THE INVENTION

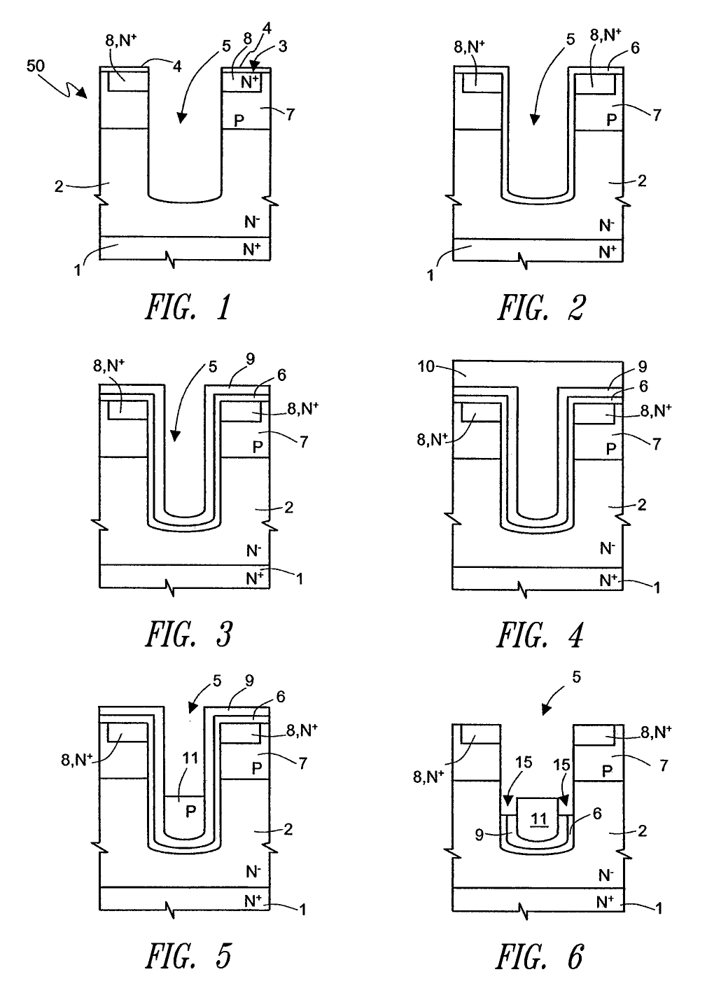

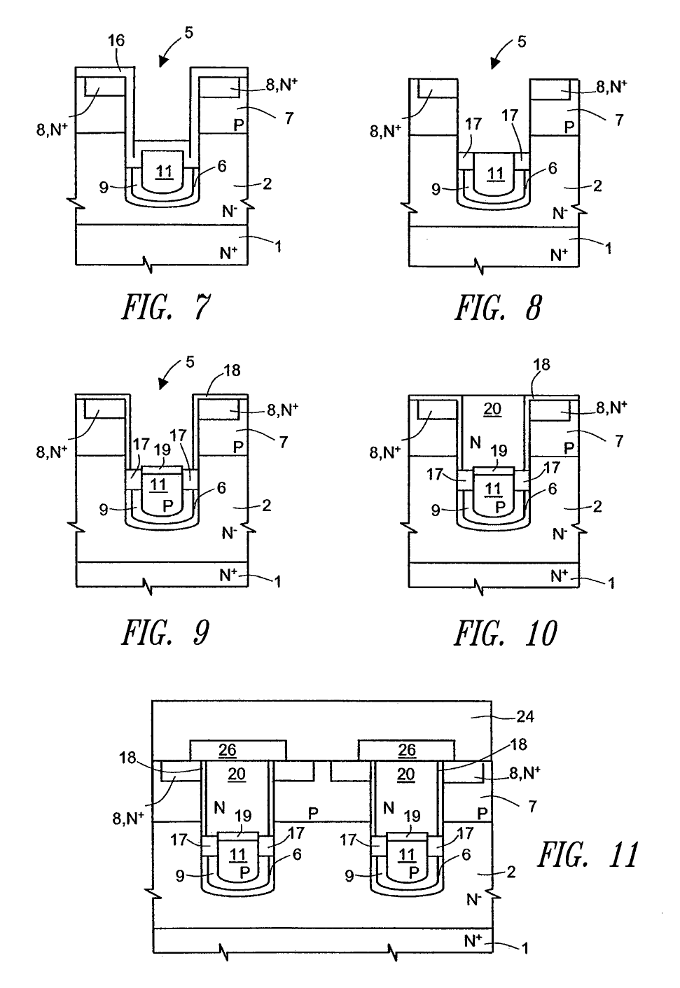

FIG. 1 shows a wafer 50 of semiconductor material that comprises a substrate 1, which is heavily doped (for example, of an N+ type for forming a power MOS or P+ type for forming an IGBT), and a semiconductor layer, which is less doped (in the example, of an N-type) and is, for example, grown epitaxially on top of the substrate 1 (epitaxial layer 2 forming a drift region). The epitaxial layer has a top surface 3, and a buffer layer, for example of an N+ type, can extend between the substrate 1 and the epitaxial layer 2.

After manufacturing edge structures and opening the active area, body regions 7 of P-type are blanket-implanted, for example, by doping the silicon with B, BF₂, Al, or In. In a way not shown, a deep enrichment of the body regions (deep body) is possibly effected in accordance with the prior art, by implanting dopants of P+ type using a resist mask; then, using another resist mask, source regions 8 of N+ type are implanted, for example, by doping silicon with As, Sb or P.

On the top surface 3 of the epitaxial layer 2 a dielectric layer is then formed, for example of deposited or thermally grown silicon oxide, or of deposited silicon nitride, or of a combination of the two materials, so as to obtain an overall thickness of 0.2-1 μm. The dielectric layer is then defined so as to form a trench mask 4 used for anisotropically dry etching the epitaxial layer 2 and forming a trench 5. The structure of FIG. 1 is thus obtained.

As is illustrated in FIG. 2, after removing the trench mask 4, and washing, a coating layer 6 of dielectric material is formed (for example, of silicon oxide having a thickness of 50-300 nm, either deposited or grown, or a multilayer, obtained by oxidation and deposition), which coats the surface 3 and the walls of the trench 5.

Then (FIG. 3), a thick oxide layer 9, for example of TEOS (tetraethyl orthosilicate) having a thickness comprised, for example, between 50 and 300 nm, is deposited by LPCVD on the coating layer 6.

Next (FIG. 4), a first polycrystalline silicon layer 10 is deposited, lightly P-type doped, which fills the trench 5; and the first polycrystalline silicon layer 10 is etched using etch back down to a depth greater than or equal to the body regions 7. Thus, a conductive region 11 remains within the trench 5, and the top surface thereof extends underneath the body regions 7 (FIG. 5).

Then (FIG. 6), the oxide on the trench wall is wet etched. The exposed portions of the thick oxide layer 9 and of the coating layer 6 are then removed, to form cavities 15 along the two sides of the trench 5, underneath the top level of the conductive region 11.

After carrying out a pad oxidation, which leads to the growth of a thin silicon oxide layer (for example of 5-25 nm, not illustrated) on the walls of the trench 5 and on the surface 3 of the epitaxial layer 2, a nitride layer 16 is deposited (FIG. 7) having a thickness equal to or greater than one half of the width of the cavities 15 (50-300 nm). In this way, the nitride layer 16 fills the cavities 15 with filling portions 17.

The nitride layer 16 and the thin silicon oxide layer are then wet etched, whereby the nitride layer 16 and the thin silicon oxide layer are completely removed, except for the filling portions 17. Then (FIG. 9), a gate oxidation is performed, thereby forming a gate insulating layer 18 on the free walls of the trench 5 and on the surface 3 of the epitaxial layer 2. A thin oxide layer 19 is moreover formed on the top surface of the conductive region 11. Then, a second polycrystalline silicon layer, heavily N-type doped, is deposited and fills the trench 5. Thereafter, the second polycrystalline silicon layer is etched back, thus forming a gate region 20 within the trench 5 (FIG. 10).

Finally, the process goes ahead with covering the structure of FIG. 10 with an insulating layer 26 of dielectric material (for example, oxide); opening the contacts by means of a dedicated photolithography; depositing a source metal layer 24 (FIG. 11); forming the final passivation; and forming a metal layer on the back side.

In this way, the polysilicon region that fills the trench is formed by two portions (the conductive region 11 and the gate region 20) with different characteristics: the conductive region 11 is in fact of P or N type, lightly doped, and is able to withstand higher breakdown voltages with a reverse biasing; moreover, it does not contribute to the parasitic capacitance associated to the gate region, while the gate region 20 can operate properly.

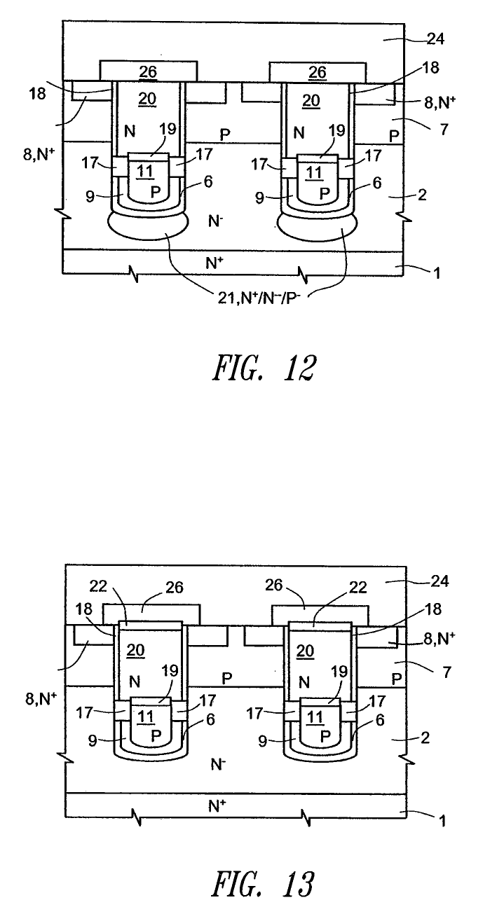

FIG. 12 shows a variant of the device of FIG. 10, wherein, after forming the trench 5, before or after forming the coating layer 6, a modified-conductivity region 21 is formed under the trench 5, by ion implanting dopant species of P or N conductivity type. In this way, the type and/or the level of doping of the epitaxial layer 2 is altered underneath the trench 5. In particular, if the implant is of the same type as the epitaxial layer 2, herein of N type, it determines a doping enrichment of the epitaxial layer 2, so that the modified-conductivity region 21 has an N+ type conductivity. This facilitates the effect, documented in the literature, of the PIN diode formed by the substrate 1, the drift region 2, and the enrichment region 21, thus reducing the output resistance of the device. If, instead, dopant species of a type opposite to the epitaxial layer 2, thus here of P type, are implanted, they cause a depletion (and the modified-conductivity region 21 is of N-type) or even a conductivity reversal (and the modified-conductivity region 21 is of P-type). In this case, a gentler slope of the electric field and hence an increase in the breakdown voltage of the device is obtained.

Furthermore, if the modified-conductivity region 21 is obtained by implant after forming the trench 5, when the trench mask 4 is still present, no other photolithographic processes for defining the implant regions are necessary. The process is consequently self-aligned with the pre-existing geometries of the device and does not lead to a sensible increase in costs.

FIG. 13 shows a third embodiment, wherein, after forming the gate region 20, a metal layer 22 is formed on the latter, for example of cobalt silicide, titanium silicide or tungsten silicide. The metal layer 22 is obtained by sputtering a thin metal layer (Co, Ti, W, etc. . . . ), sintering the metallic layer via a thermal treatment, and removing the non-sintered metal layer, via a wet etch, using, for example, turpentine.

Thereby, since the surface 3 of the epitaxial layer 2 is coated with the gate insulating layer 18, the metal layer 22 is formed only on top of the surface of the gate region 20, in a self-aligned way, i.e., it does not involve the use of additional photolithographic techniques. This variant of the method thus enables a reduction in the gate resistance to be obtained, which gate is here formed by the parallel connection of the gate region 20, of polycrystalline silicon, and of the metal layer 22, without any sensible increase in the production costs.

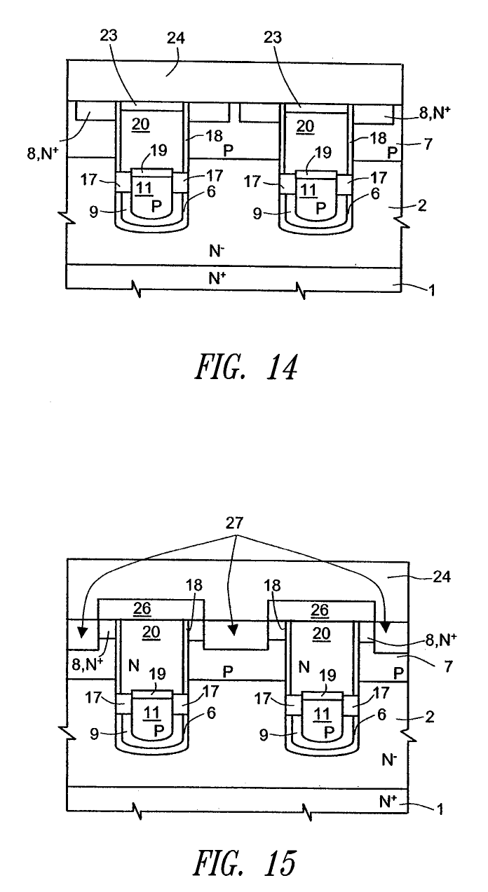

FIG. 14 relates to a variant wherein, during etch-back of the second polycrystalline silicon layer for forming the gate region 20 of the device according to any one of the first three variants described, the etching time is increased so as to remove the material of the second polycrystalline silicon layer, N-type doped, also partially from within the trench 5. The depth of the removed portion must not, however, exceed the depth of the source region 8. The part of the trench 5 that is thus free from the semiconductor material of the layer 20 is advantageously filled with a plug region 23, of dielectric material, formed by a deposition step followed by an etch-back. Finally, the source metal layer 24 is deposited over the entire surface of the device, and electrically connects the body regions 7 and the source regions 8.

Finally, FIG. 15 relates to a variant wherein the dopant species that forms the source region is blanket-implanted, i.e., without the use of masks, to obtain a source layer 8′. Furthermore, after forming the gate region 20 of the device according to any of the solutions of FIGS. 10, 11 or 12, the following steps are performed: depositing, over the entire surface of the device, an insulating layer 26 of dielectric material (for example oxide); opening the contacts using a dedicated photolithography; forming microtrenches 27 that extend from the surface of the insulating layer 26 as far as the body regions 7 and that serve to electrically connect the body regions 7 with the source layer 8′ (in particular, the microtrenches 27 must be deeper than the source layer 8′ and shallower than the body regions 7); and depositing the source metal layer 24 over the entire insulating layer 26 so as to fill the microtrenches 19.

In this way, the masking step for selective formation of source regions 8 is eliminated.

Finally, it is evident that modifications and variations can be made to the device and to the manufacturing process described herein, without departing from the scope of the present invention.

For example, the described process for forming N-channel insulated-gate power devices can likewise be applied for forming P-channel insulated-gate power devices by reversing the conductivity of the silicon substrate 1, of the epitaxial layer 2, and of the dopant species implanted in the body regions 7 and source regions 8, 8′.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

1. A power semiconductor device, comprising:
a semiconductor body having a first conductivity type and a surface;
a trench, formed in said semiconductor body and having side walls and a bottom;
an insulating structure, extending along said side walls and said bottom of said trench;
a gate region, of conductive material, extending within said trench and surrounded by said insulating structure;
a body region of a second conductivity type, extending within said semiconductor body, at sides of said trench;
a source region of said first conductivity type, extending within said semiconductor body, at the sides of said trench and on top of said body region; and a conductive region having different electrical characteristics from said gate region, said conductive region being arranged on the bottom of said trench, underneath said gate region, and being surrounded laterally and at the bottom by said insulating structure.

2. The device according to claim 1, wherein said conductive region is of polycrystalline silicon having a conductivity opposite to that of said gate region.

3. The device according to claim 2, wherein said gate region has said first conductivity type and said conductive region has said second conductivity type.

4. The device according to claim 1, wherein an insulating layer extends between said conductive region and said gate region and is connected to said insulating structure, electrically separating said conductive region and said gate region from one another.

5. The device according to claim 1, wherein said insulating structure comprises an insulating region, extending along a bottom portion of said side walls of said trench, at sides of said conductive region, and a gate insulating layer, extending along a top portion of said side walls of said trench, on top of said insulating region, at sides of said gate region, said insulating region having a thickness greater than said gate insulating layer.

6. The device according to claim 5, wherein said insulating region comprises a coating layer of a first dielectric material, in contact with said side walls and said bottom of said trench, and a thick insulating layer, of a second dielectric material, surrounded laterally and at the bottom by said insulating region.

7. The device according to claim 6, wherein said coating layer and said thick insulating layer comprise two different oxides.

8. The device according to claim 6, further comprising filling portions of silicon nitride, arranged between a top edge of said insulating region and said gate insulating layer.

9. The device according to claim 1, comprising a modified-conductivity region underneath said trench.

10. The device according to claim 1, wherein a metal silicide region extends on said gate region.

11. The device according to claim 1, comprising a dielectric material layer extending on top of said surface; an opening traversing said dielectric material layer and said source region; and a source metal layer extending on top of said dielectric material layer and inside said opening and said source region as far as said body region, said source metal layer electrically connecting said source region and said body region.

12. The device according to claim 1, wherein said gate region has a top surface extending to a level lower than said surface of said semiconductor body and overlaid by a dielectric material region.

13. A process for manufacturing a power semiconductor device, comprising the steps of:
forming a semiconductor body of a first conductivity type and having a top surface;
forming, within said semiconductor body, a body region having a second conductivity type;
forming on top of said body region, a source region having said first conductivity type,
forming, in said semiconductor body, a trench having side walls and a bottom;
coating said side walls and said bottom of said trench with an insulating structure;
forming, within said insulating structure, a gate region of conductive material; and
forming a conductive region within said insulating structure and underneath said gate region, said conductive region having different electrical characteristics from said gate region.

14. The process according to claim 13, wherein the step of forming the conductive region comprises depositing a first polycrystalline silicon layer and said step of forming the gate region comprises depositing, on top of said conductive region, a second polycrystalline silicon layer having a conductivity opposite to said first polycrystalline silicon layer.

15. The process according to claim 14, wherein said gate region has said first conductivity type and said conductive region has said second conductivity type.

16. The process according to claim 13 wherein coating said side walls and said bottom of said trench with said insulating structure further comprises:
prior to forming said conductive region, forming an insulating region along a bottom portion of said side walls of said trench; and
after forming said conductive region and prior to forming said gate region, forming a gate insulating layer along a top portion of said side walls of said trench, on top of said conductive region, said gate layer having a thickness smaller than said insulating region.

17. The process according to claim 16, wherein said step of forming said insulating region comprises forming a coating layer of a first dielectric material, in contact with said side walls and said bottom of said trench, and forming a thick insulating layer, of a second dielectric material, surrounded laterally and at the bottom by said insulating region.

18. The process according to claim 17, wherein said step of forming said insulating region comprises growing a first oxide layer in said trench and depositing a second oxide layer on said first oxide layer; after said step of forming said conductive region, etching said first and second layers so as to form said insulating region delimiting at the top a cavity; the method moreover comprising the step of filling said cavity with filling portions of silicon nitride.

19. The process according to claim 16, wherein said step of forming said gate insulating layer comprises growing an insulating layer connected to said insulating structure on top of said conductive region and prior to forming said gate region.

20. The process according to claim 13, wherein said step of forming said trench in said semiconductor body is followed by implanting dopant ion species and forming a modified-conductivity region underneath said trench.

21. The process according to claim 13, wherein said step of forming said gate region is followed by a step of forming a silicide layer made of a metal selected from the group consisting of cobalt, titanium and tungsten, on top of said gate region.

22. The process according to claim 13, wherein said step of forming said source region comprises blanket implanting a dopant species, and said step of forming the gate region is followed by the steps of:
depositing an insulating layer on said surface,
forming an opening traversing said insulating layer and said source region and extending partially into said body region; and
filling said opening with a metal.

23. The process according to claim 13, wherein said step of forming said gate region is followed by partially removing said conductive material within said trench and filling said trench with a dielectric material.

24. A semiconductor device, comprising:
a substrate of a first conductive type;
a body of the first conductive type supported by the substrate and having a lower doping concentration than the substrate, wherein the body has a top surface;
a trench formed within the body and having sidewalls and a bottom surface;
a body region of a second conductive type embedded proximate to the sidewalls of the trench;
an insulating structure extending along surfaces of the sidewalls and the bottom surface;
a source region of the first conductive type and having a higher doping concentration than the body, the source region being embedded proximate the sidewalls and the top surface;
a conductive region of the second conductive type, the conductive region being formed at the bottom surface and at least partially surrounded by the insulating structure; and
a gate region of conductive material having different electrical characteristics than the conductive region, the gate region overlying the conductive region within the trench and is at least partially surrounded by the insulating structure.

25. The semiconductor device of claim 24 wherein the conductive region is of polycrystalline silicon having a conductivity opposite that of the gate region.

26. The semiconductor device of claim 25 wherein the gate region is of the first conductive type and the conductive region is of the second conductive type.

27. The semiconductor device of claim 24 wherein an insulating layer is sandwiched between the conductive region and the gate region, the insulating layer is connected to the insulating structure, thereby electrically isolating the conductive region from the gate region.

28. The semiconductor device of claim 24 wherein the insulating structure comprises:
an insulating region extending along a bottom portion of the sidewalls and along sides of the conductive region; and
a gate insulating layer extending along a top portion of the sidewalls proximate the gate region, wherein the insulating region has a thickness greater than the gate insulating layer.

29. The semiconductor device of claim 28 wherein the insulating region comprises:
a coating layer of a first dielectric material in contact with at least a portion of the sidewalls and the bottom surface; and a thick insulating layer of a second dielectric material surrounding at least a portion of the conductive region while being surrounded by the coating layer.

30. The semiconductor device of claim 29 wherein the coating layer and the thick insulating layer comprise two different oxides.

31. The semiconductor device of claim 29, further comprising portions of silicon nitride arranged between the insulating region and the gate insulating region, wherein the portions of silicon nitride are proximate the body and the conductive region.

32. The semiconductor device of claim 24, further comprising:
a dielectric material layer overlying the top surface;
an opening formed through the dielectric material layer and the source region; and
a source metal layer overlying the dielectric material layer and filling the opening, thereby electrically connecting the source region to the body region.
